(19) United States
(12) Patent Application Publication
(10) Pub. No.: US 2004/0027119 A1
(43) Pub. Date: Feb. 12, 2004

(54) Device for long-term monitoring of magnetic fields

(76) Inventors: Michael N. Rosenheimer, Gunzelhofen (DE); Hans Schwaiger, Grobelzell (DE)

Correspondence Address: CONLEY ROSE, P.C., P.O. BOX 684908, AUSTIN, TX, 78768, US

(21) Appl. No.: 10/637,402

(22) Filed: Aug. 8, 2003

(30) Foreign Application Priority Data
Feb. 15, 2001 (DE) 101 07 188.4

(51) Int. Cl. G01R 33/02

(52) U.S. Cl. 324/244; 324/247

(57) ABSTRACT

The invention relates to a device for long-term recording of strong magnetic fields. This device comprises a magnetic field sensor as well as an analyser unit that forms signals characterising the effects of the magnetic fields from the sensor signals by integration or differentiation, and that stores these signals optionally in a memory or displays, by means of a signalling unit, that a limit has been exceeded.

### DESCRIPTION

1. Field of the Invention

The present invention relates to a device for long-term monitoring of strong magnetic fields.

Strong magnetic fields—here referred to as magnet fields that are substantially stronger than the terrestrial magnetic field—are employed in many fields of technology to an ever-increasing extent. Some typical exemplary applications will be quoted below. In the field of industry, strong magnetic fields are used to carry loads, such as lifting magnets, or also in driving technology such as in engines and motors. In nuclear physics, particle accelerators cannot be implemented without strong magnetic fields. And in advanced transportation systems, e.g. magnetic levitation trains, strong magnetic fields are used to carry and to move the train. Particularly strong magnetic fields with flow densities up to of three Tesla are employed in nuclear spin tomographs. In the future, even stronger magnetic fields must be expected to be used in further fields of application.

Such strong magnetic fields produce undesirable effects on the person and industrial equipment present within the range of the fields. The movement in magnetic fields in electrically conductive materials induces a voltage, for example. This means that voltages are induced in the components of a medical device that is moved in the vicinity of a nuclear spin tomograph, which induce voltages capable of impairing the function of the equipment or even of destroying the equipment. Moreover, interfering or dangerous voltages may equally be induced by variations of the magnetic field. The maximum variation of the field intensity in nuclear spin tomographs amounts to 600 Tesla per second. This induces, for example, a voltage of 6 Volt in a conductor loop as small as 100 cm². Such voltages are easily suitable to interfere with or damage advanced circuits operating frequently in voltage ranges from three to five Volt.

Another undesirable effect of the strong magnetic fields is the magnetisation of ferromagnetic parts as well as the demagnetisation or variation of the magnetisation of permanently magnetic parts. Strong outside magnetic fields, for instance, hence result in malfunctioning, particularly in electromechanical components such as relays or electric motors. When this threshold to malfunctioning is exceeded only slightly this effect is frequently reversible. When this threshold is very distinctly exceeded an irreversible damage occurs on the components.

2. Prior Art

In the practical application of equipment in the vicinity of strong magnetic fields attempts are made, on the one hand, to render these devices as sturdy as possible and, on the other hand, to use common measuring instruments for measuring the magnetic field strength in order to determine the maximum distance from the sources of the strong magnetic fields. This method is extremely troublesome and requires various measurements as well as different minimum distances for different devices with different levels of sensibility to magnetic fields. Moreover, field strength measuring devices available in the market do not permit a long-term recording of the measurements. Due to the cabling and the complex operation, data loggers with external field strength sensors are not applicable on a broad basis. Apart therefrom, data loggers do not permit an assessment of the influence produced by a device, which is caused by the magnetic fields, because data loggers are exclusively recording devices for long-term recording of electrical data and do not permit an evaluation of the data or at most a limited evaluation. Data loggers are, as a rule, devices that can be operated by experts only in view of their high complexity. Hence, an application of data loggers on a wide basis is doomed to fail also on account of the high costs. Moreover, devices are known which contain magnetic field sensors that switch off this device when the maximum field strength admissible is exceeded. Such a device is described, for example, in the U.S. Pat. No. 5,629,622. In that document, the amplitude of a three-dimensional magnetic field is measured by means of three sensors. The output signal is then compared against a threshold value in a comparator that generates an output signal to switch off the device. Such a switch-off, which is not intended by the operator, may result in hazardous situations particularly in medical instruments. In such devices a comparatively low switch-off threshold is determined, also In order to prevent the inexpedient consequences of a prolonged stay in strong magnetic fields. Without such a switch-off device, but with an appropriate device for long-term monitoring of the magnetic fields, it is possible to operate the equipment without malfunctioning at least for a short term, also within the range of fairly strong magnetic fields.

Apart from the effects produced on industrial equipment, strong magnetic fields take also an influence on the human body. At present, these influences have essentially not yet been studied. For instance, the irritations of muscles and nerves are known, which occur in response to variations of the magnetic fields. However, hardly any findings are available in relation to the long-term effects created by magnetic fields of medium or high intensity, to which the staff members operating in the environment of the above-described devices and instruments is exposed. In this respect, a great number of long-term studies were required. Such studies, however, cannot be performed on account of the lack of measuring means permitting a long-term measurement of the magnetic fields in the environment of the respective persons, without restricting their freedom of movement.

### BRIEF DESCRIPTION OF THE INVENTION

The invention is based on the problem of providing a device for uncomplicated long-term measurement and monitoring of strong magnetic fields, which takes the effects of the magnetic fields into consideration and which is suitable for application on a wide basis at low costs.

One inventive solution to this problem is defined in Patent Claim 1. Improvements of the invention are the subject matters of the dependent Claims.

The inventive device consists of a magnetic field sensor and an analyzer unit for evaluation of the signals of the magnetic field sensor. Moreover, at least one memory or, in an alternative, at least one signalling unit is associated with the analyzer unit. Furthermore, the analyzer unit is so designed that it processes the signals of the magnetic field sensor. What is essential here is the fact that the analyzer unit forms at least the integral with respect to time or the derivation with respect to time. In connexion with magnetic fields, these values are of a special importance. For instance, a long-term effect of the magnetic field can be taken into account via the integration of the field strength. It is known, for example, that the magnetization of many materials increases as the period of influence increases. The integral of the magnetic field with respect to time is a measure of this phenomenon.

What is equally important is the derivation of the magnetic field strength with respect to time. For example, when magnetic fields vary the induction of a voltage in a conductor or a coil, respectively, is a function of the derivation of the field strength with respect to time. Any interference in electrical or electronic circuits can, as a matter of fact, incur as a result of induced voltages. Hence the derivation of the magnetic field strength with respect to time is a measure of the potential interference by variations of the magnetic field.

The values determined from the signals of the magnetic field sensor, particularly by derivation and/or integration, can be stored in a memory associated with the analyzer unit, or can be communicated to a signalling unit. One inventive device may be configured, for example, exclusively with one or several memories when further signalling of the values is not required. The stored values are accessed exclusively via the memory that can be read by an external device to this end. It is equally possible, for example, to realise the inventive device exclusively with a signalling unit associated with the analyzer unit, when merely the determined values—or the fact that a threshold is exceeded—are to be signalled by means of a signalling means. Combinations of the afore-described variants are equally possible, however. As a result, the deviation beyond a limit can be signalled to the operator on a short-term basis and a long-term record can be retrieved from the memory. As a result, these values can be retrieved and used for documentation, for example, at a later point of time.

This storage function now permits, at option, the long-term recording or the evaluations in relation to the magnetic fields, or the recording of extreme values occurring on a short-term or long-term basis.

Hall sensors, field plates or other active or passive sensors may be used as magnetic field sensors. The description of the invention refers to sensors issuing a signal in correspondence with the magnetic field. Possibly occurring non-linearity in the characteristic graph of the sensors are corrected in the analyzer unit. In an alternative, it is also possible, for instance, to use inductive sensors. The voltage induced in a coil is proportional to the variation of the magnetic field. For this reason, such inductive sensors also produce a differentiating effect. In order to achieve an effect equivalent to the effect of aforementioned sensors, according to the present invention, the signal of such inductive sensors must still be integrated. The analyzer unit as such may be implemented, for example, in an analog form and include analog integrators or differentiators. The analyzer unit may, however, also be based on a digital circuit. In this case, an FPGA element or a micro processor or micro controller, respectively, can be employed. In such a case, the integrating or differentiating process may be performed in a numerical form. It is equally possible, to operate on combinations such as analog integration or differentiation, respectively, with a digital controller.

In a particularly expedient embodiment of the inventive device, the magnetic field sensors and the analyzer unit are integrated together in a common housing. Such integration permits a particularly space-saving structure. At the same time, it is possible to realise a closed housing without additional external links. Such a closed housing is substantially easier to shield than a plurality of housings connected to each other by means of cables. Particularly in view of the strong magnetic fields to be measured, an appropriate shielding from the influences of these fields is particularly important. One of the preferred applications of the invention is the measurement of fields in the environment of nuclear spin tomographs. Nuclear spin tomographs as such are devices emitting high-frequency energy, in addition to strong magnetic fields, and detecting extremely low signal amplitudes with an offset in time. For this reason a whole bunch of extremely high demands in terms of resistance to jamming and the emission of interference is made on equipment envisaged for operation in the environment of these nuclear spin tomographs. These demands can be satisfied most expediently with a compact device in a closed housing, without external inks. Data loggers available in the market and including external field sensors do not satisfy these requirements. Due to its non-complex and space-saving structure, the device is easy to integrate into other devices for monitoring purposes. It is equally possible, without any problems, to fasten such a small device on the clothing of staff members working within the range of the strong magnetic fields, for recording the data over long periods.

In order to achieve that this unit is also suitable for independent application it is, of course, necessary to integrate an energy source such as a battery into the housing as well. For a reduction of the power consumption of the overall arrangement, and hence for a prolongation of the service life of the battery, it is advisable to supply the magnetic field sensor, which has a comparatively high power consumption in the majority of cases, with current only by the times of measurement. This is possible because the measurements are not carried out continuously, especially in long-term measurements. For example, one measurement per second would certainly be sufficient for an informative long-term recording. The actual measuring period, which is required for the detection of the emitted signal and for its analysis, ranges in the order of 1 ms. In such a case, it is sufficient to supply the magnetic field sensor as well as amplifiers possibly associated with it and other components of the analyzer unit with current exclusively for the actual measuring period proper. This results in a transitory current ratio of the entire device of 1/1000, which leads to a service life of the battery that is correspondingly extended by the factor 1000.

An expedient improvement of the invention relates to additional means for optical or acoustic signalling. For example, optical display elements in the form of numerical or alphanumerical displays may be provided at discretion, which display actual values or the values of measurements taken in the past, as well as extreme values. Moreover, such a display may be used to configure the inventive device. This may be done, for instance, via a menu control system in correspondence with the state of the art. To this end, additional operating elements such as at least one enter key or any other sensor element are necessary, of course. Moreover, limit values can be optically displayed in a simplified form by plain signalling means such as lamps or light-emitting diodes or only by means of a plain liquid crystal field switched to the illuminated or the dark state. In such a case, a graded representation of different values is possible, too, for example by means of several coloured or individual multi-colour light-emitting diodes or by the display element flashing in different intervals. In the simplest form, however, a single light-emitting diode or lamp is provided that breaks forth when a predetermined limit value of the field strength is exceeded. An additional memory means is expedient which stores the activated state of the display element and which can be reset by the user's or service engineer's interaction. In this manner, it is possible to signal to the user at a later point of time that a maximum field strength value has been exceeded. Such signalling can be cancelled again, for example by pressing a switch or by the operation of a sensor element. For monitoring in consideration of warranty claims, it is possible to design the device in such a way that the display can be reset exclusively by an appropriately authorized service engineer. This can be done, for instance, by operation of a switch that is accessible only after the housing has been opened or by entering a secret code.

An acoustic display can be implemented with an additionally integrated loudspeaker, buzzer or any other acoustic element. In a particularly operation-friendly embodiment of the inventive device, an audio output of the essential parameters as well as a warning in the case of excessively strong magnetic fields is conceivable. In order to achieve a high insensitivity to magnetic fields here, the application of dynamic loudspeakers should be desisted from and rather piezo loudspeakers should be used instead. It is, of course, also possible to signal the information by sound at different levels and at different periods of the intervals.

In another expedient improvement of the invention, the analyzer unit comprises at least one additional limit discriminator. This limit discriminator has the function to determine whether the actually measured value or a value derived therefrom is relevant for the test. Relevant values are characterized, for example, by an outstanding amount (field strength) or by a particularly long duration. With such discrimination it is possible to prevent the storage of irrelevant signals. As a result, it becomes possible to carry out an efficient long-term recording at a substantially reduced requirement in terms of storage space, or over a substantially longer recording period at the same storage space required. Optionally, it is also possible to detect also the recording time as well as other important parameters in addition to the measured data. The limit discriminator establishes the relevance of the value by comparing the latter against a predetermined limit. According to an alternative, it is also possible to select a multi-stage limit discriminator that establishes different levels of priority of the value by comparing it against several limits. The limit or limits is/are usually invariably predetermined. Under various conditions, however, a dynamic determination of the limit is sensible as well. When, for example, a high-speed succession of relevant values following each other at short intervals generates a huge quantity of bits of information, with the first occurrence off a relevant value being important only, however, it is possible, for example, to prevent a continuing recording of data by a down time or even a dynamic adaptation of one or several limits. A downtime inhibits the limit discriminator for a predetermined period of time, thus preventing the recording of further relevant values in succession at short intervals. Such a downtime may also be dynamically adapted to the respective application. When it is established, for instance, that the limit discriminator frequently establishes relevant values again directly upon the expiration of the downtime this fact is an indicium of the persistence of the series of values to be suppressed. In order to prevent repeated recording here the downtime can now be dynamically extended. A dynamic shortening of the downtime is equally possible.

In many cases, however, another technique—the dynamic adaptation of the limit values—furnishes better results for the limit discrimination. When, for example, it is established that a limit is exceeded for the first time a new limit can be defined on the basis of the actually measured value or a value slightly higher than the previous limit. Hence, only further incidences of limit exceeding are still recorded for higher values. In order to avoid that all further recording processes will be suppressed after a non-recurring event with a special signal amount it is possible to reduce the defined limit again continuously in the course of time or in defined intervals.

When the limit discriminator has established a relevant value it signals to the memory that this value and possible additional information should be stored. Such additional information may be the time of storage, additional results of the computations based on the sensor signals or also further parameters of sensors additionally provided in the inventive device, for example.

In another expedient embodiment of the invention, the magnetic field sensor is designed as multi-dimensional field sensor. As a rule, one-dimensional field sensors can be used to measure fields correctly only which occur in a direction orthogonal on the active sensor surface. In the case of fields varying from the vertical position, the most common sensor types indicate a smaller field strength which decreases, relative to the vertical, as the cosine of the angle of the magnetic field, relative to the vertical, decreases. As, however, in the majority of applications of an inventive device, fields of the most different field strengths from various directions are to be established it is unavoidable to consider also those fields correctly which are incident on the sensor in an oblique direction. In the case of magnetic fields that are constant at least in one dimension, this is possible with a two-dimensional field sensor and in the case of optional fields with a three-dimensional field sensor. In an approach to achieve a maximum of flexibility in the application of the inventive array, the preferred embodiment comprises a three-dimensional field sensor. For this reason, the following description refers to such a three-dimensional field sensor for the sake of simplicity. The statements presented in this document—with an appropriate reduction to two dimensions—are, of course, also applicable to two-dimensional field sensors. A three-dimensional field sensor may consist, for instance, of three one-dimensional field sensors oriented in a mutually orthogonal orientation. Such a multi-dimensional field sensor can, of course, also be implemented with field sensors presenting a different orientation. The embodiment with field sensors in mutually orthogonal orientations requires, however, the lowest expenditure in the analyser unit and is hence the preferred embodiment. The analyser unit is now so designed that it establishes preferably the amount and optionally also the direction of the spatial field vector from the signal of the three field sensors.

The most important parameter in the estimation of the effect of magnetic fields is the amount or magnitude of the field. In an array constituted by three orthogonal field sensors in the directions x, y, z and with the respective field components in the x-, y- and z-direction H_{y}, H_{y}, H_{z}, it is common to compute the amount of the field strength by the equation H=Hₓ²+H_{y}²+H_{z}². When only the amount is considered a worst-case calculation can be carried out with a single numerical value. Yet there are also applications in which the direction of the magnetic field plays an important role. In the case of inductive components or devices, for example, a magnetic field in the direction of the internal magnetic flux of the component will induce undesirable voltages in the element whereas a magnetic field orthogonal thereon will hardly result in the induction of interfering voltages. In order to permit a particularly efficient evaluation of the results it is sensible to reduce the measured magnitude of a three-dimensional field vector to a numerical value. This is preferably achieved by projection via a function in which the sensibility of the object to be studied to magnetic fields is considered in the three-dimensional space. In the simplest case, the initial value of each sensor is multiplied by a predetermined factor prior to the establishment of the amount of the field strength. The result is then a single numerical value that considers the sensibility of the object to be studied to magnetic fields of any orientation whatsoever.

For a better evaluation of three-dimensional fields, it is also possible to subdivide the field sensor into several partial sensors mounted at different locations. Conclusions as to the gradient of the magnetic field can be drawn from the difference in the signals of the partial sensors. It is equally possible to consider the highest value of the various partial sensors in the evaluation as the maximum value of the field strength. With this approach, it is also possible to detect local field strength maximums better.

In a further expedient embodiment of the invention, additional means are provided for communication or for the exchange of data, respectively. With application of these means, it is possible to transmit the measured values from the memory of the device into further devices for evaluation. These means may equally be used to transfer important configuration data such as scaling factors or limits into the inventive device. To this end, computer interfaces such as RS 232, USB, Ethernet and other common standards are appropriate, which correspond preferably to the state of the art. The physical coupling may be realised via plugs and even without contact by inductive or capacitive means. Another type of communication means that can be expediently used are memory cards or modules. In this manner, the data may be exchanged also via a plug-in memory module or chip card, respectively.

A particularly expedient device comprises a magnetic field sensor as well as an analyser unit enclosed in a small housing. Such a device can be comfortably fastened by the persons to be monitored, for example in a pocket in a piece of clothing or by means of a fixing pin on a piece of clothing, similar to an X-ray dose meter. With this provision, a permanent long-term monitoring of persons is possible who may stay in the vicinity of strong magnetic fields. Such a device may also be integrated into devices that are suitable for operation in the vicinity of strong magnetic fields or that are sensitive to strong magnetic fields. The use of the device in excessively strong magnetic fields or the occurrence of strong magnetic fields, e.g. during shipment of sensitive equipment, can hence be documented later on. This is particularly important in the case of possible warranty claims.

### GENERAL REPRESENTATION OF THE DRAWINGS

The invention will be described in more details in the following, with reference to the drawings wherein:

FIG. 1 illustrates the structure of an inventive device;

FIG. 2 is a block diagram of a particularly expedient embodiment of the inventive device;

FIG. 3 is a view of a particularly simple embodiment of the inventive device, and

FIG. 4 shows an exemplary case of integration of the inventive device in a small housing.

### DESCRIPTION OF EBODIMENTS

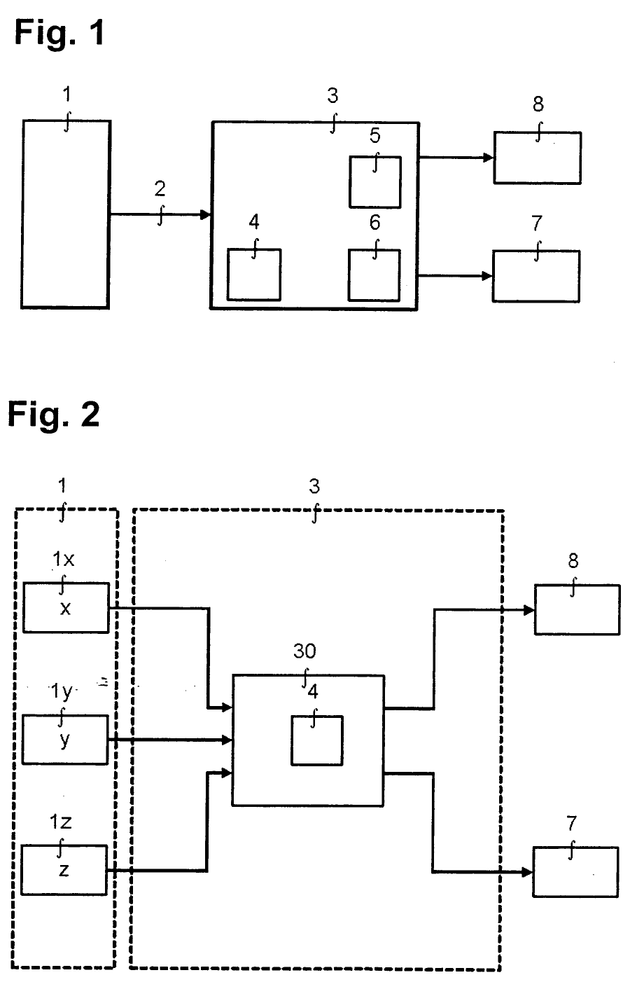

FIG. 1 illustrates the structure of an inventive device.

A magnetic field sensor (1), which may internally consist of several individual field sensors, determines the magnitude of the magnetic field. The output signal (2) of the magnetic field sensor is communicated to an analyser unit (3). The analyser unit serves to evaluate and process the senor signals. This analyser unit is optionally at least one memory (4) or a signalling unit (5), respectively. In cases where at least one memory is associated optionally either a value generated from the integral or the derivation of the sensor signals, or the scaled value of the sensor signal is written into the memory. The memory contents may be read simultaneously or at any subsequent point of time whatsoever by using a means (7) for communication.

In the case of association of a signalling unit, this unit indicates the above-described values by means of an associated display unit, or it signals that one of the aforementioned values is exceeded above at least one predefined limit. The signalling unit signals this condition by means of an additional provided signalling means (8).

The exemplary block diagram of an expedient embodiment of the invention is illustrated in FIG. 2.

According to that figure, the exemplary magnetic field sensor (1) consists of three individual partial sensors (1x, 1y, 1z) disposed in a mutually orthogonal arrangement. The signals of these partial sensors are processed in the analyser unit (3). To this end, first of all the pre-amplifiers (21x, 21y, 21z) are provided which are associated with the respective sensors and which supply the corresponding squaring elements (22x, 22y, 22z). After summation of the signals in the adder (23) and after a subsequent extraction of the root in the element (24), a signal proportional to the amount of the three-dimensional magnetic field vector is available, i.e. the amount of the magnetic field strength independent of the orientation. This signal is now supplied, for example, to an integrator (25) as well as a differentiator (26). In this example, the values of the differentiator are stored in a memory (4) and can be read out by using the means (7) for communication.

The signal of the integrator is supplied, for example, to the memory (4) for storage as well as to a limit discriminator (28) that compares this signal against a predefined limit value (27) and signals, by means of the signalling means (8) such as a light-emitting diode, when the limit is exceeded.

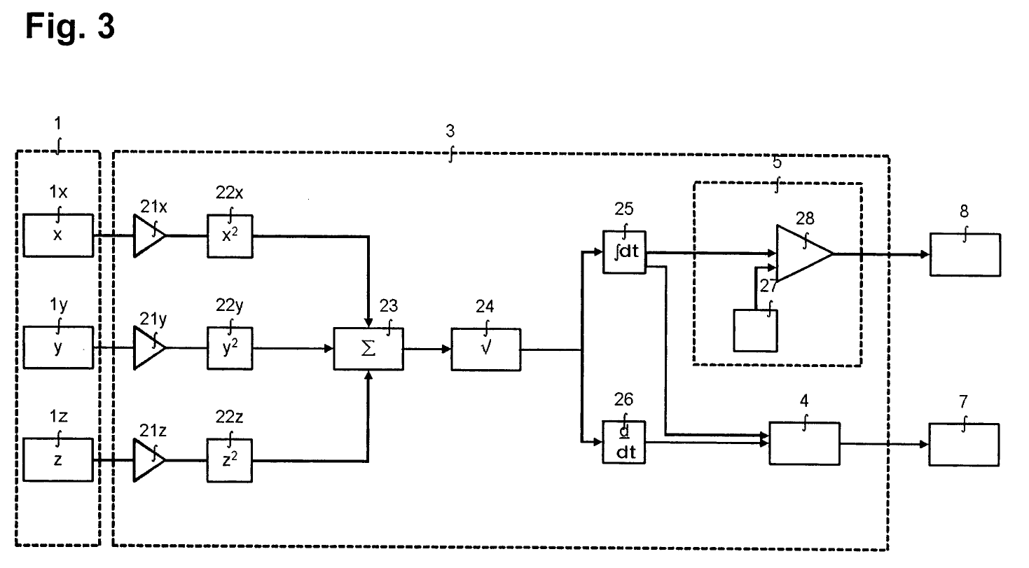

Another exemplary arrangement based on a micro controller is illustrated in FIG. 3.

In this case, the exemplary magnetic field sensor (1) consists of three individual partial sensors (1x, 1y, 1z) disposed in a mutually orthogonal arrangement. The analyser unit (3) includes, as an essential element, a micro controller (30) that comprises a memory (4) as well in this example. In this case, too, a micro controller with an external memory or even a high-performance micro processor and equally an FPGA element is appropriate. The signals of the magnetic field sensor are now supplied for processing to the micro controller directly, which presents preferably three analog input channels. This micro controller now performs the necessary numerical operations such as scaling, integration, differentiation. The results are stored in the memory (4), which can, of course, also be implemented by using an external memory device. The external communication with the memory may take place via the means (7) for communication. This means is designed for a bi-directional communication in this exemplary case so that it is not only possible to read out the values from the memory but also to store new values such as scaling factors, calibration data of the sensors or even a completely new programme into the memory of the micro controller. Moreover, an external signalling means (8) serves to signal that limits have been exceeded.

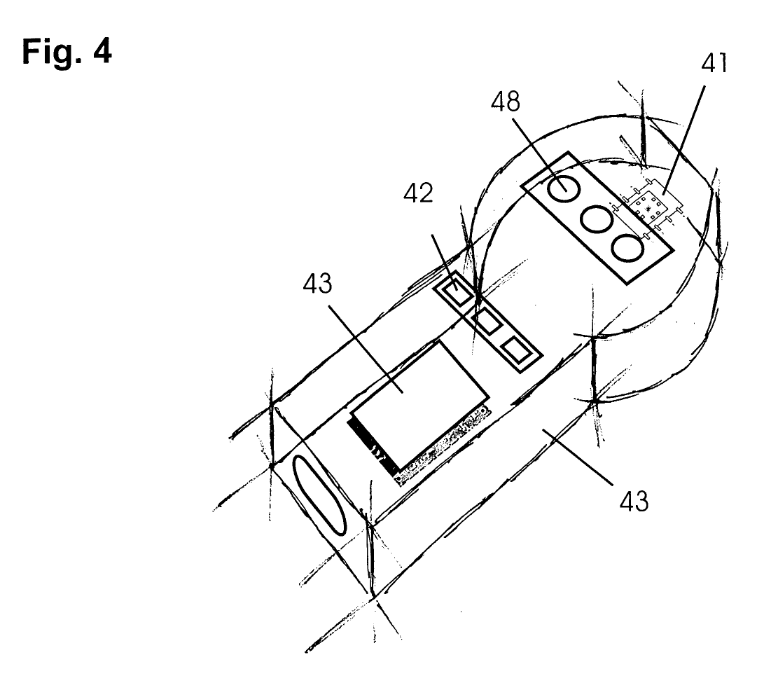

FIG. 4 is an exemplary illustration of the integration of the magnetic field sensor together with an analyser unit in a compact housing.

The housing (43) accommodates the components of the device. It consists preferably of materials influenced by the magnetic fields not at all or only to a negligible extent, at least in the region of the magnetic field sensor. The magnetic field sensor (41) in this example is disposed at the upper end of the housing so that the magnetic field to be measured will be influenced by the other components of the device as slightly as possible. The signalling means are designed, in this example, as simple display unit (48) that is capable of signalling different states with three display elements in different colours in the form of light-emitting diodes. Moreover, a keyboard (42) with three keys is provided as communication means. The micro controller (43) controls the device. In this case, it is shielded, at least partly, from excessively strong magnetic fields by a magnetic shield. For the sake of clarity, a power supply in correspondence with the state of the art and including a battery or a solar cell or operating via a cable from an external power supply is not illustrated.

1. Device for long-term measurement and monitoring of strong magnetic fields, consisting of a magnetic field sensor (1) and an analyser unit (3) for evaluation of the signals (2) from said magnetic field.sensor,
characterised in that
at least one memory (4) and/or at least one signalling unit (5) is optionally associated with said analyser unit and that said analyser unit is designed that it forms, from the signals of said magnetic field sensor, at least the integral as a function of time and/or the derivation as a function of time and stores these values in an associated memory or passes them on to a signalling unit.

2. Device according to claim 1,
characterised in that
said magnetic field sensor and said analyser unit are integrated together in a common housing.

3. Device according to claim 1 or 2,
characterised in that
at least one optical or optionally acoustical signalling means (8) is provided for indicating the measured values or for signalling that a limit has been exceeded, which signalling means is controlled by said analyser unit.

4. Device according to any of the claims 1 to 3,
characterised in that
at least one additional limit discriminator (6) is provided in said analyser unit, which compares optionally one or several values computed from the signals of said magnetic field sensor against at least one predetermined limit and signals the entry of the value to the memory when this limit has been exceeded.

5. Device according to any of the claims 1 to 4,
characterised in that
said magnetic field sensor is designed as multi-dimensional, preferably three-dimensional, field sensor and that said analyser unit is so designed that it computes at least the magnitude and optionally the orientation of the field vector from the signals of said magnetic field sensor.

6. Device according to any of the claims 1 to 5,
characterised in that
additional means are provided for communication or for data exchange, such as an interface for linking an external computer or a memory card that may be read or written by external devices.

7. Device for long-term measurement and monitoring of strong magnetic fields, consisting of a magnetic field sensor (1) and an analyser unit (3) for evaluation of the signals (2) of said magnetic field sensor,
characterised in that
said magnetic field sensor and said analyser unit are jointly accommodated in a small housing that is preferably suitable for being fastened in or on a piece of clothing or even on or in a device or its package.
